(19) United States
(12) Patent Application Publication
(10) Pub. No.: US 2019/0227171 A1
(43) Pub. Date: Jul. 25, 2019

(54) DISTANCE MEASURING DEVICE

(71) Applicant: TOPCON CORPORATION, Tokyo (JP)

(72) Inventors: Hideki MORITA, Tokyo (JP); Ken'ichiro YOSHINO, Tokyo (JP)

(73) Assignee: TOPCON CORPORATION, Tokyo (JP)

(21) Appl. No.: 16/369,670

(22) Filed: Mar. 29, 2019

Related U.S. Application Data
(63) Continuation-in-part of application No. 15/711,299, filed on Sep. 21, 2017.

(30) Foreign Application Priority Data
Sep. 28, 2016 (JP) 2016-189547

(51) Int. Cl. G01S 17/10; H05K 1/02

(52) U.S. Cl. CPC G01S 17/105; H01S 5/0428; H05K 1/0296

(57) ABSTRACT

A circuit configured to emit pulsed light includes a voltage generating circuit, a light emitting element, a circuit wiring that connects the voltage generating circuit and the light emitting element, a charge capacitor with its end connected to the circuit wiring, and a switching element configured to be turned on or off to apply voltage to the light emitting element. The inductance component for the circuit wiring is derived based on a relationship of the pattern length, pattern width and pattern thickness of the circuit wiring. In this manner, an inductance value of not greater than 1.4 nH can be set and suitably used for achieving an attenuation of at or below 3 dB in a circuit emitting light at a pulse width of 2 ns or less.

### CROSS-REFERENCE TO RELATED APPLICATIONS

This application is a continuation-in-part of pending U.S. patent application Ser. No. 15/711,299, filed Sep. 21, 2017, from which priority is claimed, which is based upon and claims the benefit of priority from Japanese Patent Application No. 2016-189547, filed Sep. 28, 2016, the contents of both of which are incorporated herein by reference in their entirety.

### TECHNICAL FIELD

The present invention relates to a circuit for emitting pulsed light.

### BACKGROUND

Distance measuring devices using pulses of light are publicly known. FIG. 1 shows a circuit of a light emitting part for measuring a distance using pulses of light (refer to Japanese Unexamined Patent Application Laid-Open No. 2010-139295). This type of circuit typically emits light with a pulse width of approximately 10 ns. A distance measuring device using this circuit tends to have laser interference due to unnecessary internal reflection in its main structure, thereby increasing deviation of distance measurement values. For this reason, an optical mechanism is then needed in the main structure to avoid the interference, which then results in increased production costs of the main structure and hindering size reduction.

Emitting light with a pulse width of 2 ns or less prevents the laser interference and enables distance measurement with high accuracy, without using the optical mechanism for avoiding the laser interference. This method provides distance measuring with high accuracy and enables an inexpensive product configuration by reducing the size of the main structure and reducing the number of parts (refer to Japanese Patent No. 3169082).

### SUMMARY

When an attempt is made to emit pulsed light with a pulse width of 2 ns or less using prior arrangements, such as the circuit shown in FIG. 1, frequency characteristics are deteriorated due to the effect of inductance of the wiring pattern of the circuit. Consequently, the prior circuit arrangements make it difficult to emit pulsed light with a pulse width of 2 ns or less in a manner that is suitable for distance measuring devices that must perform with a high degree of accuracy. An object of the present invention is to provide a technique for enabling emission of pulsed light with a pulse width of 2 ns or less and that overcomes the shortcomings of the prior arrangements.

According to an embodiment, a circuit configured to emit pulsed light includes a voltage generating circuit, a light emitting element, a circuit wiring that connects the voltage generating circuit and the light emitting element, a charge capacitor with its end connected to the circuit wiring, and a switching element configured to be turned on or off to apply voltage to the light emitting element. The inductance of the circuit wiring is set to be not greater than 1.4 nH. The light emitting element emits pulsed light with a pulse width of 2 ns or less. According to an embodiment, the inductance component for the circuit wiring is derived based on a relationship of the pattern length, pattern width and pattern thickness of the circuit wiring pattern. In this manner, an inductance value of not more than 1.4 nH can be set and suitably used for achieving an attenuation of at or below 3 dB in a circuit emitting light at a pulse width of 2 ns or less.

The claimed embodiments therefore provide a technique for enabling emission of pulsed light with a pulse width of 2 ns or less with attenuation at or below 3 dB, which provides a significant improvement over the prior arrangements.

### BRIEF DESCRIPTION OF DRAWINGS

FIG. 1 is a circuit diagram of a conventional circuit.

FIG. 2 is a circuit diagram according to an illustrative embodiment.

FIG. 3 is a graph showing a relationship, according to the claimed embodiments, between frequency and attenuation values in various wiring examples having different inductance values.

### DETAILED DESCRIPTION

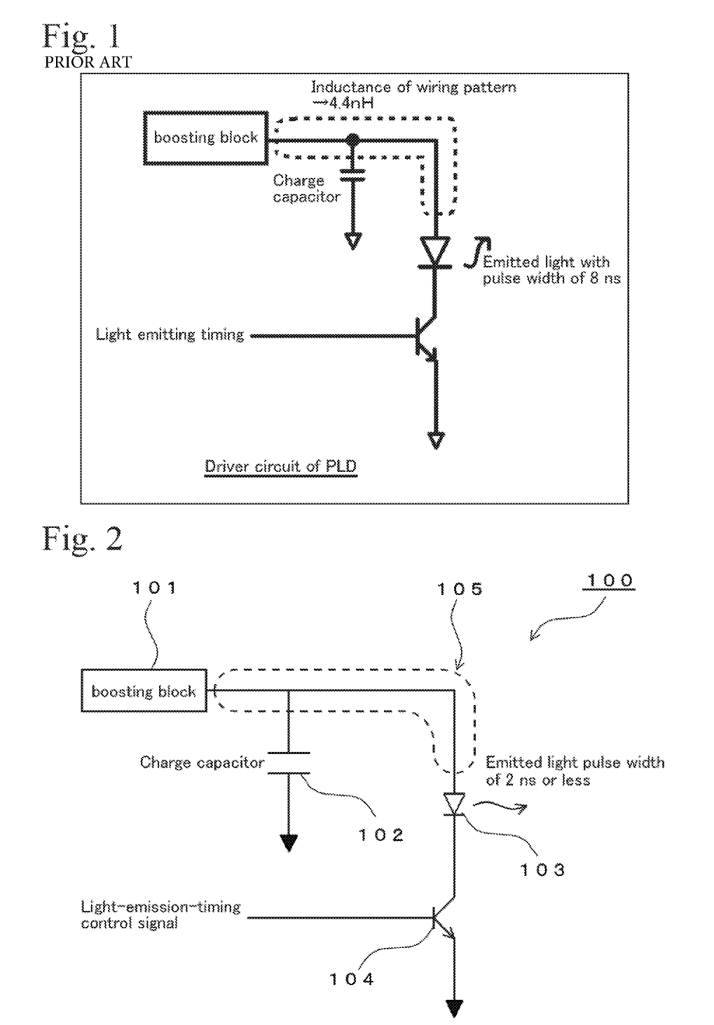

Structure. FIG. 2 shows a light emitting circuit 100 according to an embodiment of the invention. The light emitting circuit 100 includes a boosting block 101 serving as a power source, a charge capacitor 102, a laser diode 103 serving as a light emitting element, and a switching element 104. The charge capacitor 102 stores electric charges by supplying voltage from the boosting block 101. In this condition, the switching element 104 is turned on to let the electric charges, which are stored in the charge capacitor 102, instantly flow in the laser diode 103, thereby allowing the laser diode 103 to emit pulsed light.

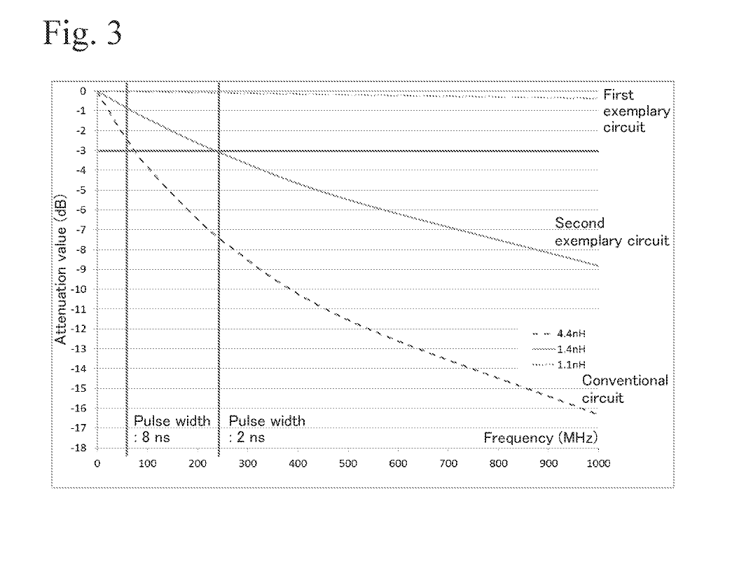

The inductance of circuit wiring 105 extending to the laser diode 103 greatly affects the pulse width of the emitted light. FIG. 3 shows a particular relationship between frequency (corresponding to a pulse width) and attenuation in each of three examples of circuit wiring having a different inductance value. As clearly shown in FIG. 3, setting the inductance of the circuit wiring 105 at not greater than 1.4 nH reduces the attenuation of light with a pulse width of 2 ns to be not greater than 3 dB, thereby enabling emission of light with a pulse width of 2 ns.

For comparison purposes, the plot associated with a conventional circuit with wiring having an inductance value of 4.4 nH is shown to achieve approximately 3 dB of attenuation, but only for light with a pulse width of approximately 8 ns, e.g., see intersection of 4.4 nH plot line with the 8 ns pulse width (left-most vertical line). For light emitted at a pulse width of 2 ns (right-most vertical line), the conventional circuit suffers from greater attenuation in the range of approximately 7 dB to 8 dB. By contrast, according to embodiments of the invention, circuits with wiring having inductance values not greater than 1.4 nH can reduce attenuation to at or below approximately 3 dB for light emitted at pulse widths of 2 ns or less, e.g., see intersection of 2 ns pulse width (vertical line) with first exemplary circuit plot line with wiring having an inductance value of 1.1 nH and second exemplary circuit plot line with wiring having an inductance value of 1.4 nH.

With the relationship that is now set forth in FIG. 3 between frequency (corresponding to pulse widths) and attenuation at different wiring inductance values, one can then understand and appreciate the effects of wiring inductance on circuit performance. Notably, by understanding the relationships set forth in FIG. 3, one will be able to realize the improvements, according to the principles of the invention, which can be achieved by setting wiring inductance values at not greater than 1.4 nH for light emitting circuits operating with pulse widths of 2 ns or less.

Hereinafter, specific examples for making the circuit wiring 105 have an inductance value of not greater than 1.4 nH will be described according to illustrative embodiments. In general, an inductance component (in μH units) of a PCB wiring pattern in circuit wiring 105 for circuit 100 is calculated by the approximation formula set forth below. Notably, the approximation formula has been found to be based on a relationship of the pattern length, pattern width and pattern thickness of the wiring pattern. Here, the symbol “L” represents a pattern length, the symbol “W” represents a pattern width, and the symbol “H” represents a pattern thickness, and units thereof are represented in mm. More specifically, a first formula for deriving the inductance component in the wiring pattern is represented by:

Inductance Component=0.0002L[ln((2×L)/(W+H))+0.2235((W+H)/L)+0.5](μH).

For comparison purposes, a conventional wiring pattern in a conventional circuit (such as shown in FIG. 1) typically has a length “L” of approximately 7 mm, a width “W” of approximately 1 mm, and a thickness “H” of approximately 18 μm, which results in an inductance of approximately 4.4 nH (refer back to discussion in the context of FIG. 3).

By contrast, and according to one illustrative embodiment of the invention, when the wiring pattern in circuit wiring 105 has a width “W” of 1 mm and a thickness “H” of 18 μm, and a length “L” of 3 mm, the inductance component is approximately 1.4 nH according to the relationship set forth above for approximating the inductance component. Referring again to FIG. 3, an inductance value of 1.4 nH can be suitably used for achieving an attenuation of at or below 3 dB in a circuit emitting light at a pulse width of 2 ns or less. In accordance with the above relationship that has been defined for the inductance component, other combinations of pattern length, width and thickness for the wiring pattern can be suitably used to set the inductance component to be not greater than 1.4 nH. For example, in order to set the inductance component to be less than (e.g., smaller than) 1.4 nH, length “L” can be made smaller while width “W” and thickness “H” are made larger. Other variations are contemplated herein. By way of example, and not by way of limitation, other exemplary values and/or ranges of values for “L”, “W”, and “H” can be as follows:

(1) “L”=2.5 mm or less, “W”=0.5 mm or more, and “H”=18 μm or more;

(2) “L”=1 to 5 mm, “W”=6 mm or more, and “H”=18 μm or more;

(3) “L”=1.9 mm or less, “W”=0.15 mm or more, and “H”=18 μm or more; and

(4) “L”=1.7 mm or less, “W”=0.1 mm or more, and “H”=18 μm or more.

As described above, the light emitting circuit 100 is configured to emit pulsed light and includes the boosting block 101 serving as a voltage generating circuit, the laser diode 103 serving as a light emitting element, the circuit wiring 105, the charge capacitor 102 with its end connected to the circuit wiring 105, and the switching element 104 configured to be turned on or off to apply the voltage to the laser diode 103. The circuit wiring 105 has an inductance of not greater than 1.4 nH. The laser diode 103 emits pulsed light with a pulse width of 2 ns or less. Setting the inductance of the circuit wiring 105 at not greater than 1.4 nH reduces the attenuation value of light with a pulse width of 2 ns or less to be not greater than 3 dB, thereby enabling emission of light with a pulse width of 2 ns or less.

What is claimed is:

1. A circuit configured to emit pulsed light, comprising:
a voltage generating circuit;
a light emitting element;
a circuit wiring that connects the voltage generating circuit and the light emitting element, wherein the circuit wiring includes a PCB wiring pattern having a pattern length (L) of 2.5 mm or less, a pattern width (W) of 0.5 mm or more, a pattern thickness (H) of 18 μm or more, and an inductance component that is set to be not greater than 1.4 nH for reducing an attenuation of pulsed light, emitted from the light emitting element and having a pulse width of 2 ns, to not exceed 3 dB, wherein the inductance component is set as a function of the following relationship:
0.0002L[ln((2×L)/(W+H))+0.2235((W+H)/L)+0.5](μH), where
L is the pattern length in mm units,
W is the pattern width in mm units, and
H is the pattern thickness in mm units;
a charge capacitor with its end connected to the circuit wiring; and
a switching element configured to be turned on or off to apply voltage to the light emitting element.

2. A circuit configured to emit pulsed light, comprising:
a voltage generating circuit;
a light emitting element;
a circuit wiring that connects the voltage generating circuit and the light emitting element, wherein the circuit wiring includes a PCB wiring pattern having a pattern length (L) of 1 mm to 5 mm, a pattern width (W) of 6 mm or more, a pattern thickness (H) of 18 μm or more, and an inductance component that is set to be not greater than 1.4 nH for reducing an attenuation of pulsed light, emitted from the light emitting element and having a pulse width of 2 ns, to not exceed 3 dB, wherein the inductance component is set as a function of the following relationship:
0.0002L[ln((2×L)/(W+H))+0.2235((W+H)/L)+0.5](μH), where
L is the pattern length in mm units,
W is the pattern width in mm units, and
H is the pattern thickness in mm units;
a charge capacitor with its end connected to the circuit wiring; and
a switching element configured to be turned on or off to apply voltage to the light emitting element.

3. A circuit configured to emit pulsed light, comprising:
a voltage generating circuit;
a light emitting element;
a circuit wiring that connects the voltage generating circuit and the light emitting element, wherein the circuit wiring includes a PCB wiring pattern having a pattern length (L) of 1.9 mm or less, a pattern width (W) of 0.15 mm or more, a pattern thickness (H) of 18 μm or more, and an inductance component that is set to be not greater than 1.4 nH for reducing an attenuation of pulsed light, emitted from the light emitting element and having a pulse width of 2 ns, to not exceed 3 dB, wherein the inductance component is set as a function of the following relationship:
0.0002L[ln((2×L)/(W+H))+0.2235((W+H)/L)+0.5](μH), where
L is the pattern length in mm units,
W is the pattern width in mm units, and
H is the pattern thickness in mm units;
a charge capacitor with its end connected to the circuit wiring; and
a switching element configured to be turned on or off to apply voltage to the light emitting element.
